(19) United States
(12) Patent Application Publication
(10) Pub. No.: US 2013/0149820 A1
(43) Pub. Date: Jun. 13, 2013

(54) METHOD FOR MANUFACTURING SEMICONDUCTOR DEVICE

(71) Applicants: Chien-Chung Huang, Taichung City (TW); Kuo-Chih Lai, Tainan City (TW)

(72) Inventors: Chien-Chung Huang, Taichung City (TW); Kuo-Chih Lai, Tainan City (TW)

(21) Appl. No.: 13/323,763

(22) Filed: Dec. 12, 2011

(51) Int. Cl. H01L 21/8238

(52) U.S. Cl. 438/199; 257/E21.632

(57) ABSTRACT

A method for manufacturing a semiconductor device includes providing a substrate having a first transistor device and a second transistor device formed thereon; forming a patterned stress film covering the second transistor device and exposing the first transistor device on the substrate; performing a pre-amorphous implantation (PAI) process to form an amorphous layer respectively at two sides of the first transistor device, and removing the patterned stress film.

### BACKGROUND OF THE INVENTION

1. Field of the Invention

The present invention generally relates to a method for manufacturing a semiconductor device, and more particularly, to a method for manufacturing a semiconductor device integrated with stress memory technique (hereinafter abbreviated as SMT).

2. Description of the Prior Art

Generally, a plurality of process technologies is currently practiced in the field of semiconductor production. For example, self-aligned silicide (salicide) process has been widely used in semiconductor fabrication.

In metal-oxide-semiconductor field effect transistor (MOSFET) technologies, a silicide may be implemented for reliable contact and less contact resistance. The silicide may be used to provide an interface between metal lines and substrate contact regions, such as a polysilicon gate, a silicon source, and a silicon drain. Placing metal silicide on the source and drain regions may reduce the sheet resistance (Rs) of the path between the metal contact and the underlying structure. However, a MOSFET includes semiconductor material other than silicon. For example, the MOSFET may include germanium, silicon-germanium (SiGe), even or gallium arsenide (GaAs). It is well-known that reaction rates of the metal to the semiconductor materials mentioned-above are all different, therefore the thickness of the formed metal silicides may vary depending on the type of semiconductor material used. Furthermore, the thickness of the metal silicide influences sheet resistance very much, it is found that when a semiconductor device includes metal silicides of un-uniform thickness, resistance matching is getting difficult and complicated. The metal silicides having different thickness even worsen performance of the semiconductor device.

As such, a method for manufacturing a semiconductor device being able to solve the abovementioned problem is still in need.

### SUMMARY OF THE INVENTION

According to an aspect of the present invention, a method for manufacturing a semiconductor device is provided. The method includes providing a substrate having a first transistor device and a second transistor device formed thereon; forming a patterned stress layer on the substrate, the patterned stress film covering the second transistor device but exposing the first transistor device; performing a pre-amorphous implantation (PAI) process to form an amorphous layer respectively at two sides of the first transistor device; and removing the patterned stress film.

According to the method for manufacturing a semiconductor device provided by the present invention, all the thermal treatments required for forming the patterned stress film have been performed before the PAI process, thus the patterned stress film is obtained without impacting the amorphous layer, which is formed by the PAI process. In other words, the method provided by the present invention protects the amorphous layer from any thermal treatment, therefore the process result of the silicide process is always improved due to the unaffected amorphous layer. Furthermore, when the method provided by the present invention is integrated with SMT, no extra layer for protecting the semiconductor device, in which no amorphous layer should be formed, is required during the PAI process. Briefly speaking, the method for manufacturing a semiconductor device provided by the present invention is able to maintain the amorphized state and thus to improve the result of the silicide process without increasing process complexity and cost.

These and other objectives of the present invention will no doubt become obvious to those of ordinary skill in the art after reading the following detailed description of the preferred embodiment that is illustrated in the various Figures and drawings.

### BRIEF DESCRIPTION OF THE DRAWINGS

FIGS. 1-6 are schematic drawings illustrating a method for manufacturing a semiconductor device provided by a preferred embodiment of the present invention, wherein

FIG. 2 is a schematic drawing in a step subsequent to FIG. 1,

FIG. 3 is a schematic drawing in a step subsequent to FIG. 2,

FIG. 4 is a schematic drawing in a step subsequent to FIG. 3,

FIG. 5 is a schematic drawing in a step subsequent to FIGS. 4, and

FIG. 6 is a schematic drawing in a step subsequent to FIG. 5.

### DETAILED DESCRIPTION

Please refer to FIGS. 1-6, which are schematic drawings illustrating a method for manufacturing a semiconductor device provided by a preferred embodiment of the present invention. As shown in FIG. 1, the preferred embodiment first provides a substrate 100 having a first region 102 and a second region 104 defined thereon. A first transistor device 110 and a second transistor device 112 are respectively formed in the first region 102 and the second region 104. And a plurality of shallow trench isolations (STIs) 106 providing electrical isolation is formed between the first transistor device 110 and the second transistor device 112 in the substrate 100. The first transistor device 110 includes a first conductivity type and the second transistor device 112 includes a second conductivity type. In the preferred embodiment, the first conductivity type and the second conductivity type are complementary. For example, the first transistor device 110 is a p-type transistor device while the second transistor device 112 is an n-type transistor device.

As shown in FIG. 1, the first transistor device 110 and the second transistor device 112 respectively include a gate structure 108, and the gate structure 108 sequentially includes a gate dielectric layer 108a, a gate conductive layer 108b, and a patterned hard mask 108c for defining the gate structure 108 from bottom to top. Although reference numerals of the gate structures in both the first transistor device 110 and the second transistor device 112 are marked 108 for simplifying, please note they could use different materials or structures. The first transistor device 110 and the second transistor device 112 further respectively include a first light doped drain (LDD) 120 and a second LDD 122, a spacer 124, and a first source/drain 130 and a second source/drain 132. It is noteworthy that to improve the device performance, the carrier mobility, and driving current, strained silicon technique is introduced in the preferred embodiment. According to the preferred embodiment, recesses (not shown) are formed in the substrate 100 respectively at two sides of the first transistor device 110 after forming the spacer 124. Subsequently, a selective epitaxial growth (SEG) process is performed to form an epitaxial silicon-germanium (SiGe) layer along the surface of the substrate 100 exposed in the bottom and sidewalls of the recesses. Furthermore, ion implantation can be performed before forming the recesses, during the SEG process, or after the SEG process, to form the recessed first source/drain 130 as shown in FIG. 1. Because the lattice constant of the epitaxial SiGe layer is larger than that of the silicon, such characteristic is employed to cause alteration to the band structure of the silicon in the channel region of the substrate 100. Accordingly, the carrier mobility and the speed performance of the first transistor device 110 are improved.

Please still refer to FIG. 1. Next, an insulating layer 140 is blanketly formed on the substrate 100. According to the preferred embodiment, the insulating layer 140 includes a silicon nitride layer, but not limited to this.

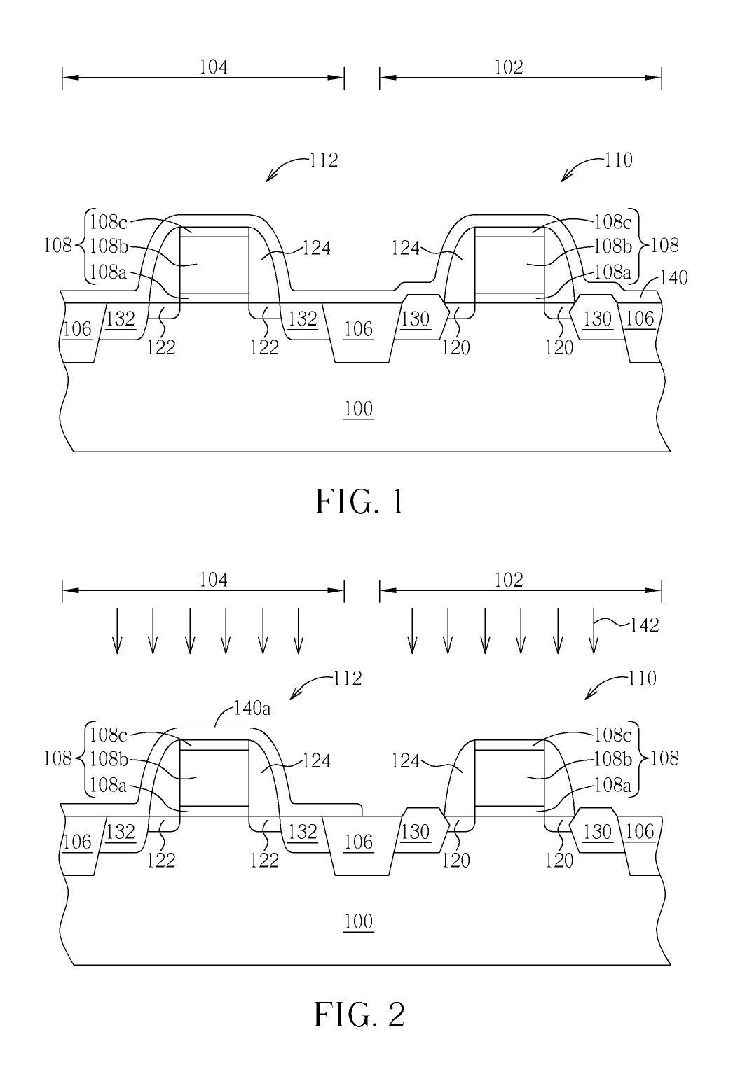

Please refer to FIG. 2. After forming the insulating layer 140, a portion of the insulating layer 140 is removed to expose the first transistor device 110. Subsequently, a thermal treatment 142, such as a Laser rapid thermal process (Laser RTP) is performed to the insulating layer 140 with a high temperature of about 1000° C. to adjust a tensile stress of the insulating layer 140. Accordingly, a patterned stress film 140a is formed in the second region 104, particularly formed on the second transistor device 112. Because the patterned stress film 140a covers only the second transistor device 112 but exposes the first transistor device 110, the tensile stress provided by the patterned stress film 140a expands the lattice arrangement of the channel region of the second transistor device 112 in the substrate 100 without rendering impact to the first transistor device 100. Consequently, the drive current of the second transistor device 112 is improved.

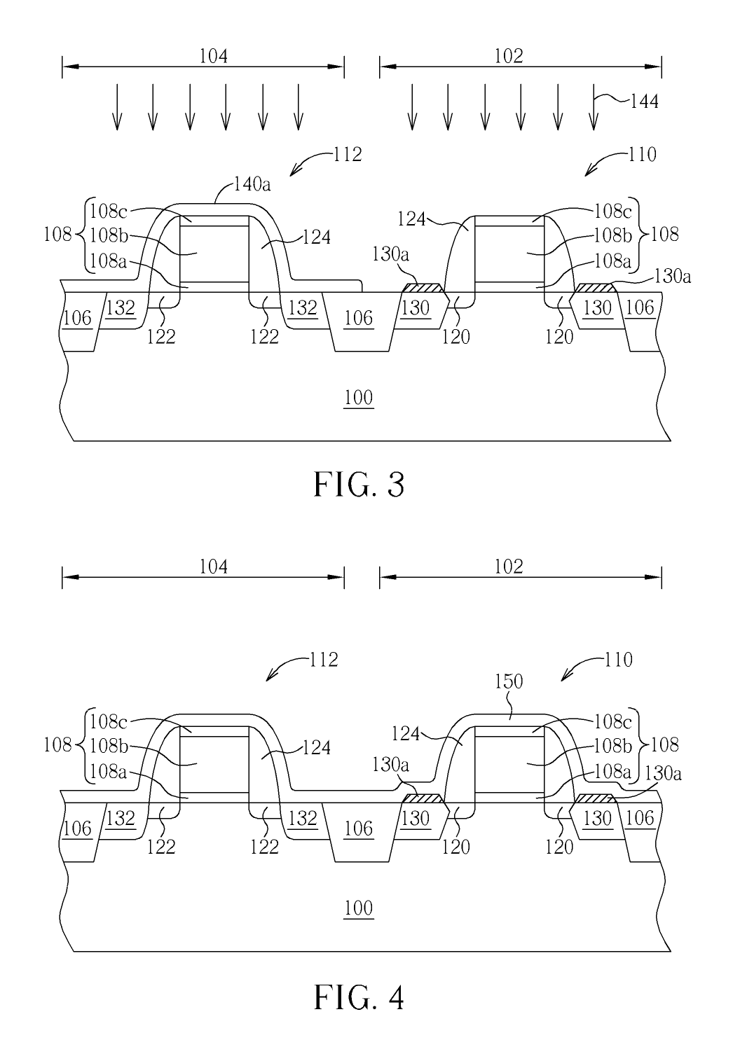

Please refer FIG. 3. Because interface between the epitaxial layer of the first source/drain 130 and the substrate 100 may cause sizable amounts of variability, the following formed elements, such as the silicide layer formed on surface of the first source/drain 130 and the second source/drain 132, may lack uniformity. When a semiconductor device includes silicides of different thickness, resistance matching becomes difficult and complicated. The different thickness of the silicides even deteriorate performance of the semiconductor device. Therefore the preferred embodiment provides a pre-amorphous implantation (PAI) process 144 performed after forming the patterned stress film 140a, particularly after the thermal treatment 142. Consequently, an amorphous layer 130a is formed respectively in the first source/drain 130 of the first transistor device 110. In other words, the PAI process 144 is to amorphize a portion of the strained-silicon structure of the first source/drain 130, thus the amorphous layer 130a is formed on the surface of the strained-silicon structure. As shown in FIG. 3, the amorphous layer 130a is non-coplanar with the substrate 100. That is, a surface of the amorphous layer 130a is higher than a surface of the substrate 100. It is noteworthy that because the second transistor device 112 is protected by the patterned stress film 140a, the PAI process 144 renders no impact to the second transistor device 112 at all. In other words, the patterned stress film 140a replaces the protection layer required in the PAI process 144, and serves to protect the second transistor device 112 from the PAI process 144. Accordingly, the PAI process 144 forms the amorphous layer 130a only in the first region 102 without forming any other protection layer.

Please refer to FIG. 4. After the PAI process 144, the patterned stress film 140a is removed and followed by performing a self-aligned silicide (salicide) process: First, a metal layer 150 is formed on the substrate 100. The metal layer 150 exemplarily includes nickel (Ni), platinum (Pt), titanium (Ti), or cobalt (Co), but not limited to this.

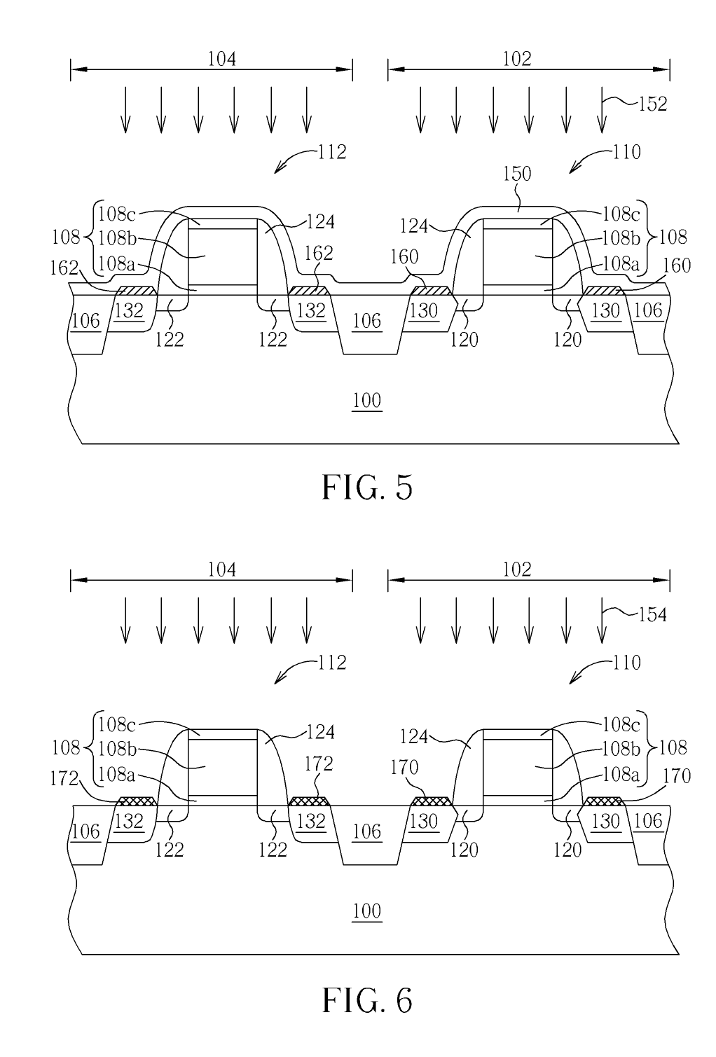

Please refer to FIG. 5. Next, a thermal treatment 152 is performed to the metal layer 150, thus the metal layer 150 reacts with the silicon in the first source/drain 130 and the second source/drain 132. Accordingly, a first intergraded silicide 160 and a second integrated silicide 162 are respectively formed on surfaces of the first source/drain 130 and the second source/drain 132. It is noteworthy that the first intergraded silicide 160 is obtained from the reaction of the metal layer 150 and the epitaxial SiGe. In general, the reaction rate of the metal layer 150 and the epitaxial SiGe in the amorphous layer 130a in the first source/drain 130 is much lower than that of the metal layer 150 and silicon in the second source/drain 132. Therefore the thickness of the first intergraded silicide 160 and the second integrated silicide 162 supposed to be different. As a countermeasure against to that problem, the preferred embodiment provides the PAI process 144 to damage the epitaxial SiGe structure in the first source/drain 130 and to form the amorphous layer 130a. Accordingly, the reaction rate of the metal layer 150 and the amorphous layer 130a is accelerated. Subsequent to forming the first intergraded silicide 160 and the second intergraded silicide 162, the metal layer 150 is removed.

Please refer to FIG. 6. After removing the metal layer 150, another thermal treatment 154 is performed to transfer the first intergraded silicide 160 and the second intergraded silicide 162 to respectively form a first silicide 170 on the amorphous layer 130a of the first source/drain 130 and a second silicide 172 on the second source/drain 132. For example, when the metal layer 150 is a Ni layer, the first silicide 170 includes nickel germanosilicide (NiSiGe) and the second silicide 172 includes nickel silicide (NiSi). More important, the first metal silicide 170 and the second silicide 172 include a same thickness as shown in FIG. 6.

Please note that the material of the second source/drain 132 is not limited to silicon in the above example. Epitaxial SiC is also possible. As long as the silicidation rates differ between the first source/drain 130 and the second source/drain 132, the present invention is applicable.

According to the method for manufacturing a semiconductor device provided by the present invention, all the thermal treatments required for forming the patterned stress film have been performed before the PAI process, thus the patterned stress film is obtained without impacting the amorphous layer, which is formed by the PAI process. In other words, the method provided by the present invention protects the amorphous layer from any thermal treatments, therefore the process result of the silicide process is always improved due to the unaffected amorphous layer. Furthermore, when the method provided by the present invention is integrated with SMT, no extra layer for protecting the semiconductor device, in which no amorphous layer should be formed, is required during the PAI process. Briefly speaking, the method for manufacturing a semiconductor device provided by the present invention is able to maintain the amorphized state and thus to improve the result of the silicide process without increasing process complexity and cost.

Those skilled in the art will readily observe that numerous modifications and alterations of the device and method may be made while retaining the teachings of the invention. Accordingly, the above disclosure should be construed as limited only by the metes and bounds of the appended claims.

1. A method for manufacturing a semiconductor device comprising:
providing a substrate having a first transistor device and a second transistor device formed thereon, the first transistor device comprising a first source/drain and the second transistor device comprising a second source/drain;
forming an insulating layer on the substrate covering the first source/drain and the second source/drain;
removing a portion of the insulating layer to expose the first transistor device;
performing a first thermal treatment to form a patterned stress film on the substrate, the patterned stress film covering the second transistor device but exposing the first transistor device;
performing a pre-amorphous implantation (PAI) process to form an amorphous layer respectively at two sides of the first transistor device; and
removing the entire patterned stress film.

2. The method for manufacturing a semiconductor device according to claim 1, wherein the first transistor device comprises a first conductivity type and the second transistor device comprises a second conductivity type.

3. The method for manufacturing a semiconductor device according to claim 2, wherein the first conductivity type and the second conductivity type are complementary.

4. (canceled)

5. The method for manufacturing a semiconductor device according to claim 1, wherein the PAI process is performed after the first thermal treatment.

6. The method for manufacturing a semiconductor device according to claim 1, wherein the amorphous layer is non-coplanar with the substrate.

7. The method for manufacturing a semiconductor device according to claim 1, further comprising performing a silicide process after removing the patterned stress film.

8. The method for manufacturing a semiconductor device according to claim 7, wherein a first silicide and a second silicide are respectively formed on the first source/drain and the second source/drain by the silicide process.

9. The method for manufacturing a semiconductor device according to claim 8, wherein the first source/drain comprises a strained-silicon structure.

10. The method for manufacturing a semiconductor device according to claim 9, wherein the strained-silicon structure comprises at least silicon-germanium (SiGe).

11. The method for manufacturing a semiconductor device according to claim 9, wherein the PAI process is performed to amorphosize the strained-silicon structure and to form the amorphous layer on a surface of the strained-silicon structure.

12. The method for manufacturing a semiconductor device according to claim 11, wherein the silicide process further comprises:
forming a metal layer on the substrate;
performing a second thermal treatment to form an intergraded silicide respectively on the amorphous layer and the second source/drain;
removing the metal layer; and
performing a third thermal treatment to transform the intergraded silicides to form the first silicide and the second silicide.

13. The method for manufacturing a semiconductor device according to claim 12, wherein the first silicide and the second silicide comprise a same thickness.
